(19) United States
(12) Patent Application Publication
(10) Pub. No.: US 2023/0290423 A1
(43) Pub. Date: Sep. 14, 2023

(54) METHOD AND APPARATUS FOR TESTING MEMORY CHIP, STORAGE MEDIUM, AND ELECTRONIC DEVICE

(71) Applicant: CHANGXIN MEMORY TECHNOLOGIES, INC., Hefei (CN)

(72) Inventor: Jing WANG, Hefei (CN)

(21) Appl. No.: 17/849,729

(22) Filed: Jun. 27, 2022

Related U.S. Application Data
(63) Continuation of application No. PCT/CN2022/090619, filed on Apr. 29, 2022.

(30) Foreign Application Priority Data
Mar. 11, 2022 (CN) 202210237604.2

(51) Int. Cl. G11C 29/42; G11C 29/44; G11C 29/46; G11C 29/12

(52) U.S. Cl. CPC G11C 29/42; G11C 29/4401; G11C 29/46; G11C 29/1201

(57) ABSTRACT

Provided are a method for testing a memory chip, an apparatus for testing a memory chip, a computer-readable storage medium and an electronic device, which relate to the field of semiconductor technology. The method includes: determining a memory block corresponding to each of cores in a multi-core processor, the memory block being a local memory area comprising a part of memory cells in the memory chip; and performing a read-write test on the corresponding memory block by means of each of the cores in the multi-core processor, and determining a test result of the memory chip according to a test result of each of memory blocks obtained from the test. Utilization rate of the multi-core processor is improved, and test efficiency of the memory chip is improved.

### CROSS-REFERENCE TO RELATED APPLICATION

This application is a continuation of PCT/CN2022/090619, filed on Apr. 29, 2022, which claims priority to Chinese Patent Application No. 202210237604.2, titled “METHOD AND APPARATUS FOR TESTING MEMORY CHIP, STORAGE MEDIUM, AND ELECTRONIC DEVICE” and filed on Mar. 11, 2022, the entire contents of which are incorporated herein by reference.

### TECHNICAL FIELD

The present disclosure relates to the field of semiconductor technology, and more particularly, to a method for testing a memory chip, an apparatus for testing a memory chip, a computer-readable storage medium, and an electronic device.

### BACKGROUND

Memory chips are constituent elements of most electronic products. To ensure service performance of the memory chips, semiconductor manufacturers generally test the memory chips before delivery to check the service performance of the memory chips.

At present, to improve test efficiency of the memory chips such as Dynamic Random Access Memory (DRAM), the manufacturers generally choose a multi-tasking operating system for testing. However, the operating system may occupy a part of memory space because it runs in the DRAM, and this part of memory space cannot be tested, resulting in insufficient test comprehensiveness of the entire memory chips.

### SUMMARY

According to a first aspect of the present disclosure, there is provided a method for testing a memory chip. The method includes: determining a memory block corresponding to each of cores in a multi-core processor, the memory block being a local memory area comprising a part of memory cells in the memory chip; and performing a read-write test on the corresponding memory block by means of each of the cores in the multi-core processor, and determining a test result of the memory chip according to a test result of each of memory blocks obtained from the test.

In an exemplary embodiment of the present disclosure, the memory chip is divided into a plurality of memory blocks by: dividing the memory chip into the plurality of memory blocks having memory areas of an equal size or different sizes according to a memory address of each of the memory cells in the memory chip.

In an exemplary embodiment of the present disclosure, the determining a memory block corresponding to each of cores in a multi-core processor includes: determining the memory block corresponding to each of the cores according to address information of the memory block corresponding to each of the cores in the multi-core processor, where the address information includes a memory address of each of the memory cells included in each of the memory blocks in the memory chip. The performing a read-write test on the corresponding memory block by means of each of the cores in the multi-core processor includes: performing the read-write test on the corresponding memory block by means of each of the cores in the multi-core processor until the read-write test is completed for all memory blocks in the memory chip, to obtain the test result of each of the memory blocks.

In an exemplary embodiment of the present disclosure, the performing a read-write test on the corresponding memory block by means of each of the cores in the multi-core processor further includes: simultaneously performing the read-write test on any one or more corresponding memory blocks by means of each of the cores in the multi-core processor; or sequentially performing the read-write test on any one or more corresponding memory blocks by means of each of the cores in the multi-core processor.

In an exemplary embodiment of the present disclosure, the test result of each of the memory blocks includes a fact whether a read-write error occurs in a memory cell in the corresponding memory block and number of bits of an address where the read-write error occurs. The determining a test result of the memory chip according to a test result of each of the memory blocks obtained from the test includes: determining a memory cell where the read-write error occurs from the memory chip and the number of bits of the address of the memory cell where the read-write error occurs according to the test result of each of the memory blocks, to obtain the test result of the memory chip.

In an exemplary embodiment of the present disclosure, before the performing a read-write test on the corresponding memory block by means of each of the cores in the multi-core processor, the method further includes: loading and running a bootloader by means of the multi-core processor to activate each of the cores in the multi-core processor, such that when each of the cores is in an activated state, the read-write test is performed on the corresponding memory block. The bootloader runs in a static random access memory (SRAM), and each of the cores runs in the bootloader when in the activated state.

In an exemplary embodiment of the present disclosure, when performing a read-write test on the corresponding memory block by means of each of the cores in the multi-core processor, the method further includes: when performing the read-write test on each of the memory blocks, determining a test strategy for each of the memory blocks in the memory chip, where the test strategy includes test procedures for performing a data read operation and/or data write operation on each of the memory blocks; and performing the data read operation and/or data write operation, by each of the cores in the multi-core processor, on each of the corresponding memory blocks according to the test procedures.

In an exemplary embodiment of the present disclosure, the test strategy further includes test data of each of the test procedures. The performing the data read operation and/or data write operation, by each of the cores in the multi-core processor, on each of the corresponding memory blocks according to the test procedures further includes: determining target test data for a currently executed test procedure; and performing the data read operation and/or data write operation, by each of the cores, on the target test data in each of the corresponding memory blocks according to the currently executed test procedure.

In an exemplary embodiment of the present disclosure, the method further includes: when all the cores in the multi-core processor complete the read-write test on each of the corresponding memory blocks according to the currently executed test procedure, controlling each of the cores to perform the read-write test on each of the corresponding memory blocks according to a next test procedure.

In an exemplary embodiment of the present disclosure, the method further includes: during performing the read-write test on each of the corresponding memory blocks, when any one or more cores in the multi-core processor complete the read-write test on each of the corresponding memory blocks according to the currently executed test procedure, controlling the any one or more cores to enter a wait state, and triggering a counter to count; and when determining that all the cores in the multi-core processor enter the wait state according to a counting result of the counter, reactivating each of the cores in the multi-core processor, and controlling each of the cores to perform the read-write test on each of the corresponding memory blocks according to the next test procedure.

In an exemplary embodiment of the present disclosure, the test strategy further includes an operation procedure for performing a global control operation on the memory cells in the memory chip. The method further includes: performing, by any one of the cores in the multi-core processor, the global control operation on all the memory cells in the memory chip according to the operation procedure of the global control operation. The global control operation includes a data retention operation and/or data refresh operation performed on the memory cells in the memory chip.

In an exemplary embodiment of the present disclosure, the method further includes: when there is any one or more memory blocks having not been tested, monitoring a test progress for each of the cores, and performing the read-write test on any one of the any one or more memory blocks by means of cores in the multi-core processor having completed the test, until the read-write test is completed for all the memory blocks in the memory chip.

In an exemplary embodiment of the present disclosure, the memory chip includes a dynamic random access memory (DRAM).

According to a second aspect of the present disclosure, there is provided an apparatus for testing a memory chip. The apparatus includes: a determination circuit, configured to determine a memory block corresponding to each of cores in a multi-core processor, where the memory block is a local memory area comprising a part of memory cells in the memory chip; and a test circuit, configured to perform a read-write test on the corresponding memory block by means of each of the cores in the multi-core processor, and determine a test result of the memory chip according to a test result of each of memory blocks obtained from the test.

In an exemplary embodiment of the present disclosure, the determination circuit divides the memory chip into a plurality of memory blocks by: dividing the memory chip into the plurality of memory blocks having memory areas of an equal size or different sizes according to a memory address of each of the memory cells in the memory chip.

In an exemplary embodiment of the present disclosure, the determination circuit is configured to determine the memory block corresponding to each of the cores according to address information of the memory block corresponding to each of the cores in the multi-core processor, where the address information includes a memory address of each of the memory cells included in each of the memory blocks in the memory chip. The test circuit is configured to perform the read-write test on the corresponding memory block by means of each of the cores in the multi-core processor until the read-write test is completed for all memory blocks in the memory chip, to obtain the test result of each of the memory blocks.

In an exemplary embodiment of the present disclosure, the test circuit is further configured to: simultaneously perform the read-write test on any one or more corresponding memory blocks by means of each of the cores in the multi-core processor; or sequentially perform the read-write test on any one or more corresponding memory blocks by means of each of the cores in the multi-core processor.

In an exemplary embodiment of the present disclosure, the test result of each of the memory blocks includes a fact whether a read-write error occurs in a memory cell in the corresponding memory block and number of bits of an address where the read-write error occurs. The test circuit is further configured to determine, according to the test result of each of the memory blocks, a memory cell where the read-write error occurs from the memory chip and the number of bits of the address of the memory cell where the read-write error occurs, to obtain the test result of the memory chip.

In an exemplary embodiment of the present disclosure, before performing a read-write test on the corresponding memory block by means of each of the cores in the multi-core processor, the test circuit is further configured to load and run a bootloader by means of the multi-core processor to activate each of the cores in the multi-core processor, such that when each of the cores is in an activated state, the read-write test is performed on the corresponding memory block. The bootloader runs in the SRAM, and each of the cores runs in the bootloader when in the activated state.

In an exemplary embodiment of the present disclosure, when performing a read-write test on the corresponding memory block by means of each of the cores in the multi-core processor, the test circuit is further configured to determine, when performing the read-write test on each of the memory blocks, a test strategy for each of the memory blocks in the memory chip, where the test strategy includes test procedures for performing a data read operation and/or data write operation on each of the memory blocks. Each of the cores in the multi-core processor performs the data read operation and/or data write operation on each of the corresponding memory blocks according to the test procedures.

In an exemplary embodiment of the present disclosure, the test strategy further includes test data of each of the test procedures, and the test circuit is further configured to determine target test data for a currently executed test procedure. Each of the cores performs the data read operation and/or data write operation on the target test data in each of the corresponding memory blocks according to the currently executed test procedure.

In an exemplary embodiment of the present disclosure, the test circuit is further configured to control each of the cores to perform the read-write test on each of the corresponding memory blocks according to a next test procedure when all the cores in the multi-core processor complete the read-write test on each of the corresponding memory blocks according to the currently executed test procedure.

In an exemplary embodiment of the present disclosure, the test circuit is further configured to, during performing the read-write test on each of the corresponding memory blocks, when any one or more cores in the multi-core processor complete the read-write test on each of the corresponding memory blocks according to the currently executed test procedure, control the any one or more cores to enter a wait state, and trigger a counter to count. Moreover, the test circuit is further configured to, when determining that all the cores in the multi-core processor enter the wait state according to a counting result of the counter, reactivate each of the cores in the multi-core processor, and control each of the cores to perform the read-write test on each of the corresponding memory blocks according to the next test procedure.

In an exemplary embodiment of the present disclosure, the test strategy further includes an operation procedure for performing a global control operation on the memory cells in the memory chip. The test circuit is further configured to perform, by any one of the cores in the multi-core processor, the global control operation on all the memory cells in the memory chip according to the operation procedure of the global control operation. The global control operation includes a data retention operation and/or data refresh operation performed on the memory cells in the memory chip.

In an exemplary embodiment of the present disclosure, the test circuit is further configured to: when there is any one or more memory blocks having not been tested, monitor a test progress for each of the cores, and perform the read-write test on any one of the any one or more memory blocks by means of cores in the multi-core processor having completed the test, until the read-write test is completed for all the memory blocks in the memory chip.

In an exemplary embodiment of the present disclosure, the memory chip includes a dynamic random access memory (DRAM).

According to a third aspect of the present disclosure, there is provided a computer-readable storage medium storing a computer program thereon, the computer program is executable by a processor, whereby the method for testing a memory chip according to any one of the above embodiments is implemented.

According to a fourth aspect of the present disclosure, there is provided an electronic device, which includes a processor and a memory configured to store executable instructions of the processor. The processor is configured to perform the method for testing a memory chip by executing the executable instructions.

### BRIEF DESCRIPTION OF THE DRAWINGS

FIG. 1 shows a flowchart of a method for testing a memory chip according to this exemplary embodiment;

FIG. 2 shows an example of a method for determining a memory block according to this exemplary embodiment;

FIG. 3 shows a sub-flow diagram of a method for testing a memory chip according to this exemplary embodiment;

FIG. 4 shows a structural block diagram of an apparatus for testing a memory chip according to this exemplary embodiment;

FIG. 5 shows a computer-readable storage medium configured for implementing the above method according to this exemplary embodiment; and

FIG. 6 shows an electronic device configured to implement the above method according to this exemplary embodiment.

### DETAILED DESCRIPTION

Exemplary embodiments will now be described more comprehensively with reference to the accompanying drawings. However, the exemplary embodiments can be embodied in many forms and should not be construed as being limited to the embodiments set forth herein; rather, these embodiments are provided such that the present disclosure will be made thorough and complete, and the concept of the exemplary embodiments will be fully conveyed to those skilled in the art. Furthermore, the described features, structures, or characteristics may be combined in any suitable manner in one or more embodiments. In the following description, numerous details are provided to provide a thorough understanding of the embodiments of the present disclosure. Those skilled in the art will recognize, however, that the technical solution of the present disclosure may be practiced without one or more of the details described, or that other methods, components, devices, steps and so on may be employed. In other instances, well-known technical solutions are not shown or described in detail to avoid obscuring aspects of the present disclosure.

In addition, the accompanying drawings are merely exemplary illustration of the present disclosure, and are not necessarily drawn to scale. The same reference numerals in the drawings denote the same or similar parts, and thus repeated description thereof will be omitted. Some block diagrams shown in the figures are functional entities and not necessarily to be corresponding to a physically or logically individual entities. These functional entities may be implemented in software form, or implemented in one or more hardware circuits or integrated circuits, or implemented in different networks and/or processor apparatuses and/or microcontroller apparatuses.

The flowcharts as shown in the accompanying drawings are merely exemplary description instead of necessarily including all the steps. For example, some steps may be broken down, while some steps may be combined or partly combined. Therefore, the actual execution sequences may be changed according to the actual conditions. In addition, all the following terms “first”, “second” and “third” are for the purpose of distinction only, and should not be used as a limitation on contents of the present disclosure.

An exemplary embodiment of the present disclosure first provides a method for testing a memory chip. This method may be used for respectively performing a read-write test on local memory areas in the memory chip by means of a plurality of cores of a multi-core processor to detect read-write performance of the memory chip, and this method may also be used for realizing flexible test of the memory chip to improve test efficiency of the memory chip. In this exemplary embodiment, the memory chip may be a dynamic random access memory, i.e., a DRAM, which may be a semiconductor memory including a plurality of memory cells. Each of the plurality of memory cells is a cell in the memory chip having data storage and data read-write functions. From the perspective of constituent structure, one of the plurality of memory cells may comprise one transistor and one capacitor. One binary bit 0 or 1 may be represented by controlling number of charges stored in the capacitor. Generally, the memory chip may include a plurality of memory cells, and the plurality of memory cells may be arranged in any shape. For example, the plurality of memory cells may be arranged in a memory array in any shape.

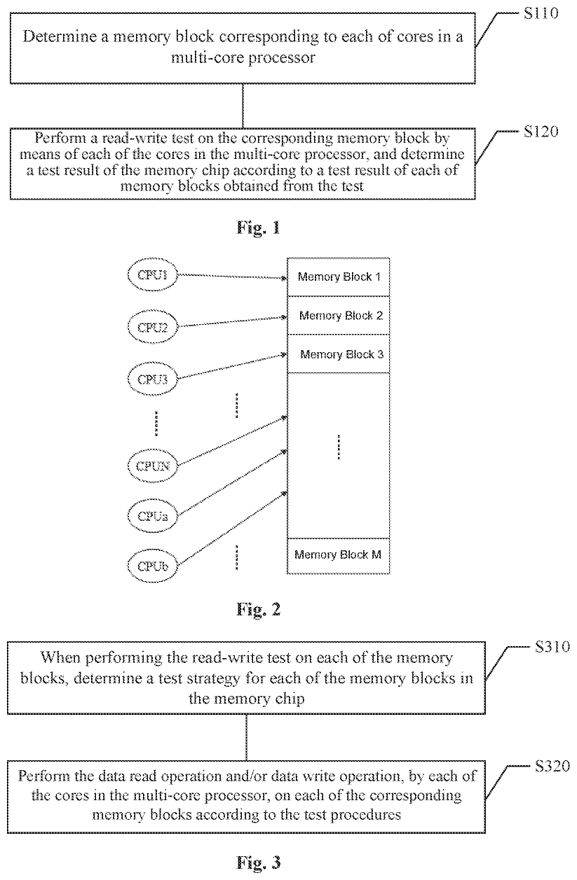

FIG. 1 shows a flowchart according to this exemplary embodiment, which may include following Steps S110 to S120.

Step S110: determining a memory block corresponding to each of cores in a multi-core processor.

The memory block refers to a local memory area comprising a part of memory cells in the memory chip. For a plurality of memory blocks, number of memory cells included in each of the plurality of memory blocks may be the same or may be different. The multi-core processor refers to integrating two or more complete computing engines (i.e., cores) into one processor. At this moment, the processor can support a plurality of processors on a system bus, and a bus controller provides all bus control signals and command signals. The multi-core processor may decompose a task to be processed into a plurality of parts, and assign each of the plurality of parts to different core registers such that a plurality of operators can operate jointly. After operation results are summarized, the summarized operation results are processed by one arithmetic unit and then distributed for a next step, or the operation results may be directly distributed for the next step by means of program control.

In this exemplary embodiment, the memory chip may be divided into a plurality of memory blocks, and during the test, a memory block corresponding to each of the cores may be determined first. For example, as shown in FIG. 2, CPU1, CPU2, CPU3 . . . CPUN, CPUa and CPUb represent different cores. According to a rule that one core corresponds to any one of plurality of memory blocks, each of the plurality of memory blocks in the memory chip is assigned to each of the cores in the multi-core processors. For example, a memory block corresponding to the CPU1 is denoted as a memory block 1. In this way, each of the plurality of memory blocks corresponding to each of the cores is different from each other. Through this method, each of the plurality of memory blocks (i.e., a combination of cells comprising a plurality of memory cells) corresponding to each of the cores may be determined, thereby achieving effective grouping of the memory cells, which contributes to improving test flexibility of the memory chip.

As memory capacity of the memory chip increases, number of memory cells in the memory chip is increasing. To determine a memory block corresponding to each of the cores in the multi-core processor, in an embodiment, the memory chip may be first divided into the plurality of memory blocks having memory areas of an equal size or different sizes according to a memory address of each of the memory cells in the memory chip. The memory address is a number of a memory cell in the memory chip, and this number can uniquely identify one memory cell.

Each of the memory cells in the memory chip may be divided into a plurality of memory blocks according to a memory address of each of the memory cells in the memory chip, where a size of each of the plurality of memory blocks may be arbitrary, and in each of the plurality of memory blocks, the memory cells may be adjacent or may be not adjacent to each other. For example, X memory cells with contiguous memory addresses may be divided into one memory block according to the memory address of each of the memory cells, such that the memory chip may be divided into a plurality of memory blocks according to continuity of the memory addresses. X is a positive integer. For another example, each row of memory cells or each column of memory cells having the same row address or column address may be divided into one memory block according to the memory address of each of the memory cells. That is, a memory cell may be divided into a plurality of memory blocks according to a relationship between rows and columns of the memory cells constituting a memory array in the memory chip. By dividing each of the memory cells in the memory chip into a plurality of memory blocks, arbitrary grouping of the memory cells can be completed, and grouping rules may be customized by testers. In this way, a variety of different testing and grouping requirements can be met, and higher flexibility can be provided.

Based on the above method, when determining a memory block corresponding to each of the cores in the multi-core processor, in an embodiment, the memory block corresponding to each of the cores may be determined according to address information of the memory block corresponding to each of the cores in the multi-core processor. The address information may include a memory address of each of the memory cells included in each of the memory blocks in the memory chip. For example, for N cores in the multi-core processor, memory blocks corresponding to each of the N cores may be sequentially determined according to order of addresses of the memory blocks. For another example, based on a rule that one core corresponds to a fixed number of memory cells, the memory block corresponding to each of the cores may be determined to be a memory area comprising X memory cells in the memory chip according to the memory address of each of the memory cells in the memory chip. That is, one core corresponds to X memory cells, and the memory cells in the memory block corresponding to each of the cores are not repeated.

In addition, in an embodiment, an address correspondence between each of the cores and each of the memory blocks may be pre-configured by the testers. For example, the testers may establish a configuration table in advance according to the address correspondence between each of the cores and each of the memory blocks, such that when a memory block corresponding to each of the core is determined, the memory block corresponding to each of the cores and the memory address of the memory cell in the memory block may be determined according to the configuration table. In this way, the memory block corresponding to each of the cores can be found in the memory chip.

The memory address may uniquely identify the memory cell, so each of the memory cells in the memory block corresponding to each of the cores may be ensured to have uniqueness by means of the above method of determining a memory block corresponding to each of the cores according to the address information of the memory block. That is, memory cells in any two of the memory blocks are not repeated, which can solve a problem of lower test efficiency caused by testing repeated units and a problem of test disorder, thereby avoiding having a negative effect on test results.

Step S120: performing a read-write test on the corresponding memory block by means of each of the cores in the multi-core processor, and determining a test result of the memory chip according to a test result of each of memory blocks obtained from the test.

The read-write test refers to fully writing or fully reading the memory cells of the memory chip to be tested, or traversing in a manner of reading first and then writing or other different read/write combinations. The test result is configured for representing a fact whether a read-write error occurs in each of the memory cells, for example, whether there is a memory cell where data cannot normally written or the read data is inconsistent with the written data.

After the memory block corresponding to each of the cores is determined, a read-write test may be performed on the corresponding memory block by means of each of the cores, to determine, by each of the cores, a test result of each of memory blocks. Next, the multi-core processor may perform analysis and processing (such as statistics, deduplication, and so on) on the test result of each of the memory blocks, to determine the test result of the memory chip. In this way, the multi-core processor can simultaneously run a plurality of cores to perform a test task, so the test efficiency of the memory chip can be significantly improved.

To ensure test comprehensiveness of the memory chip, in an embodiment, before Step S120, following step may also be performed:

loading and running a bootloader by means of the multi-core processor to activate each of the cores in the multi-core processor, such that when each of the cores is in an activated state, the read-write test is performed on the corresponding memory block.

The bootloader is a first piece of code executed after an embedded system is powered on. The bootloader may initialize a hardware device and establish a mapping table of memory space. That is, an appropriate system software and hardware environment is built to get ready for calling each of the cores in the multi-core processor. The bootloader may run in a static random access memory (SRAM), and each of the cores runs in the bootloader when in the activated state. That is, in the activated state, each of the cores executes the test task for each of the memory blocks respectively. At this moment, each of the cores runs in the bootloader. As a memory with static access functions, the SRAM can save data internally stored without refreshing when it is in a powered-on state.

For a computer system, in the process from power-on to staring an operating system, the multi-core processor may load and run the bootloader to complete booting of the process, and activate each of the cores in the multi-core processor to complete multi-core scheduling of the test tasks for the memory chip, such that each of the cores may perform the read-write test on the corresponding memory blocks in the activated state. When performing the test task, each of the cores runs in the bootloader of the SRAM, so no memory space of the memory chip is occupied. Therefore, the comprehensive test requirements of the memory chip can be met, and the test efficiency of the memory chip can be improved.

In the multi-core processor, each of the cores may be configured to independently complete processing tasks. Therefore, to implement the read-write test for each of the memory blocks, in an embodiment, following step may be performed to implement the read-write test for each of the memory blocks:

performing the read-write test on the corresponding memory block by means of each of the cores in the multi-core processor until the read-write test is completed for all memory blocks in the memory chip, to obtain the test result of each of the memory blocks.

The read-write test is performed on the corresponding memory block by each of the cores. For example, a certain number of cores may be controlled to simultaneously perform the read-write test on their corresponding memory blocks. After the read-write test is completed, each of the cores may obtain its test result for its corresponding memory block. Meanwhile, when one core corresponds to two or more memory blocks, this core may perform the read-write test on its associated memory blocks in sequence until the test is completed for all memory blocks corresponding to this core. Through this method, the cores in the multi-core processor may be controlled to test the memory blocks according to established rules, such that different test requirements can be met.

Further, in an embodiment, following step may also be performed:

simultaneously performing the read-write test on any one or more corresponding memory blocks by means of each of the cores in the multi-core processor; or sequentially performing the read-write test on any one or more corresponding memory blocks by means of each of the cores in the multi-core processor.

When each of the cores simultaneously performs the read-write test on different memory blocks, each of the cores simultaneously executes a test program for the different memory blocks. In this case, each of the cores runs in parallel, so processing performance of the multi-core processor can be maximized, and the test efficiency of the memory chip can be improved. When each of the cores sequentially performs the read-write test on different memory blocks, each of the cores sequentially executes the test program for the different memory blocks. In this case, asynchronous running of the cores may be implemented, such that processing flexibility of the cores in the multi-core processor can be brought into full play. For example, at the current moment, one core may perform a write test procedure, and another core may perform a read test procedure. Through the above method, the multi-core processor may be controlled to perform the read-write test on the memory blocks according to different running modes, which has higher flexibility.

In this exemplary embodiment, the test methods for each of the memory blocks may be the same or may be different. For example, the test method for a certain memory block may be expressed as a test algorithm primitive: (w), (r, w), (r), (w), (r, w, r), (r), where this method needs to traverse the memory cells of the memory chip for six times. The test method of another memory block may be expressed as a test algorithm primitive: (w, r), (w), (r), (w), where this method only needs to traverse the memory cells of the memory chip for four times. The (w) or (r) indicates that a write operation or read operation is performed on all the memory cells of the memory chip. The (r, w) indicates to perform the read operation and then the write operation on the memory cells of the memory chip according to a size of one access, such as 1 byte, 4 bytes, or 8 bytes and so on, to traverse all the memory cells of the memory chip. The (r, w, r) indicates to perform the read operation, the write operation and then the read operation on the memory cells of the memory chip according to the size of one access, to traverse all the memory cells of the memory chip. In the above process, data written twice may be the same or may be different. Based on this, in an embodiment, when performing a read-write test on the corresponding memory block by means of each of the cores in the multi-core processor, referring to FIG. 3, following step may also be performed:

Step S310: when performing the read-write test on each of the memory blocks, determining a test strategy for each of the memory blocks in the memory chip.

The test strategy may include test procedures for performing a data read operation and/or data write operation on each of the memory blocks. The test procedures refer to a stage of data read-write operation on each of the memory blocks. The data read-write operation on the same test data may be regarded as one test procedure, or any one data read operation or data write operation may be regarded as one test procedure. The test procedure may include an operation sequence and frequency of performing the data read-write operation on each of the memory blocks. In addition, the test strategy may also include test parameters when performing the data read operation or data write operation, such as a voltage value of a control signal, and the like.

When performing the read-write test on associated memory blocks by means of each of the cores, the test procedure may be predetermined for each of the memory blocks. For example, operation steps to be performed for each of the memory blocks and sequence of each of the operation steps or the like may be searched and determined according to a preconfigured test rule table.

Step S320: performing the data read operation and/or data write operation, by each of the cores in the multi-core processor, on each of the corresponding memory blocks according to the test procedures.

During the test, the multi-core processor may control each of the cores to perform the data read-write operation on the corresponding memory blocks according to unified test procedures. Through this method, it may be ensured that each of the memory blocks is tested by the unified test procedures to ensure consistency, comprehensiveness and accuracy of the test. Meanwhile, because the test procedures may be configured by the testers, flexibility and convenience of the test may also be improved.

Further, for different test procedures, test data written to or read from the memory blocks may be different. Therefore, in an embodiment, the test strategy may also include the test data in the test procedures. Step S320 may also be implemented by:
determining target test data for a currently executed test procedure; and
performing the data read operation and/or data write operation, by each of the cores, on the target test data in each of the corresponding memory blocks.

The test data refer to written data set for testing read/write functions of the memory cells. Because the memory chip stores data in a binary form, the test data may also be any binary sequence. The target test data refers to test data to be read or written in the currently executed data read operation or data write operation.

In this exemplary embodiment, the multi-core processor may control each of the cores to perform a test task on a corresponding memory block. When performing the test task, each of the cores may determine a currently executed test procedures, i.e., the target test data corresponding to the data read operation and/or data write operation, such that each of the cores writes the target test data in the corresponding memory block or reads the target test data therefrom. Through this method, when writing the test data, correctness of written data in each test stage can be ensured, and when reading the test data, it may also be determined whether the read data is correct according to the read data and the test data. In this way, efficiency of determining the test results can be improved, and the testers may also set different test data for different test stages to meet test requirements of each stage.

In addition, the data read-write operation in the test procedures may be performed sequentially. Therefore, in an embodiment, when all the cores in the multi-core processor complete the read-write test on each of the corresponding memory blocks according to the currently executed test procedure, each of the cores may be controlled to perform the read-write test on each of the corresponding memory blocks according to a next test procedure.

For a test task with a plurality of test procedures, each of the cores executes each of the plurality of test procedures in sequence, and only when each of the cores completes a current test procedure for each of the memory blocks will the next test procedure be performed for each of the memory blocks. Therefore, test errors can be avoided to a certain extent.

In this exemplary embodiment, the memory blocks may have different sizes, and each of the cores in the multi-core processor may also have different speeds. Therefore, even at the beginning of the test, each of the cores corresponds to each of the memory blocks in access order. However, with switching of the test procedures or repeated access to the memory blocks, each of the cores may execute different test procedures at the same time, resulting in test errors of the memory blocks. Therefore, to implement the synchronous test of each of the cores, in an embodiment, following steps may also be performed:
during performing the read-write test on each of the corresponding memory blocks, when any one or more cores in the multi-core processor complete the read-write test on each of the corresponding memory blocks according to the currently executed test procedure, controlling the any one or more cores to enter a wait state, and triggering a counter to count; and
when determining that all the cores in the multi-core processor enter the wait state according to a counting result of the counter, reactivating each of the cores in the multi-core processor, and controlling each of the cores to perform the read-write test on each of the corresponding memory blocks according to the next test procedure.

In the wait state, the cores do not perform the test tasks. For example, when the multi-core processor controls each of the cores to start testing the corresponding memory blocks, each of the cores is activated one by one, and count continues to increase by 1. When a value of count is equal to the total number of the activated cores, all the cores enter the wait state. That is, synchronization of the cores is completed, and then the multi-core processor may control the activated cores to execute the test procedures for the corresponding memory blocks according to corresponding memory block allocation rules. When a certain core completes the currently executed test procedure, the multi-core processor may control this core to enter the wait state, while the counter may count, such as count minus 1. As the other cores also successively complete the currently executed test procedure, the counter is continuously triggered to decrease by 1 until it is reset. At this moment, all the cores entering the wait state may be reactivated, and the counter may be triggered to increase by 1 until all the cores return to the wait state, all the cores are controlled to execute the next test procedure. The count represents number of cores in the wait state at the current moment. When it is determined that all the cores enter the wait state according to the counting result of the counter, it means that all the cores have completed the currently executed test procedure. At this moment, the multi-core processor may control each of the cores to execute the next test procedure on the corresponding memory blocks. This method may ensure that the cores can complete the test procedures within specified limit, ensure the synchronization of executing the test procedures for the cores, prevent disorder of the test procedures from causing false errors in the test results, avoid erroneous determination, and improve the test accuracy.

When testing the memory chip, sometimes it is required to perform some non-access operations on the memory chip. Therefore, in an embodiment, the test strategy may further include an operation procedure for performing a global control operation on the memory cells in the memory chip. The global control operation is the non-access operation performed on the memory chip, and the global control operation may include a data retention operation and/or data refresh operation performed on the memory cells in the memory chip. In some embodiments, the data retention operation refers to controlling the data written into the memory chip to retain for a period of time, to ensure that the written data does not change unexpectedly due to factors such as time or leakage. The data refresh operation refers to performing periodic charging operation on high-potential capacitors in the memory cells, which can maintain stability of the high-potential capacitors such that the memory cells can continuously store data. The data refresh operation may include a self-refresh operation or a controller-controlled refresh operation, etc.

Therefore, when the read-write test is performed on each of the memory blocks, any one of the cores in the multi-core processor may also perform the global control operation on all the memory cells in the memory chip according to an operation procedure for the global control operation. For example, after completing any one or more test procedures, the multi-core processor may control the core that finally completes the test procedure to perform the data retention operation and the data refresh operations on all the memory cells in the memory chip, where execution time of these operations may be preset by the testers. By performing the global control operation, continuous storage of data may be ensured during the read-write test of the memory chip, thereby preventing external factors from having a negative effect on subsequent test results.

Further, as previously mentioned, one core may correspond to one or more memory blocks. In this way, as shown in FIG. 2, when number N of the cores in the multi-core processor is equal to number M of the memory blocks, completion of the read-write test for all the cores means termination of the entire test task. When the number N of the cores in the multi-core processor is greater than the number M of the memory blocks, completion of the read-write test for all the cores to which the memory blocks are allocated also means the termination of the entire test task. When the number N of the cores in the multi-core processor is smaller than the number M of the memory blocks, and when all the cores complete the read-write test, there are still remaining memory blocks in the memory chip, at this moment, to complete the read-write test for the remaining memory blocks, in an embodiment, following steps may also be performed:
when there is any one or more memory blocks having not been tested, monitoring a test progress for each of the cores, and performing the read-write test on any one of the any one or more memory blocks by means of cores in the multi-core processor having completed the test, until the read-write test is completed for all the memory blocks in the memory chip.

In the above method, the memory blocks correspond to the cores one to one. When one of the cores completes the test of its corresponding memory block, the multi-core processor may detect memory blocks having not been tested, such that the read-write test is performed on the memory blocks having not been tested by means of the cores having completed the test. For example, in an example of memory block division as shown in FIG. 2, assuming that a CPUa is the core that completes the test the earliest, for the remaining untested memory blocks, that is, the (N+1)^{th} memory block, the read-write test may be first performed on the (N+1)^{th} memory block by means of the CPUa, and meanwhile the test progress is monitored for all the cores, and then the read-write test is performed on the (N+2)^{th} memory block by means of a CPUb that has completed the read-write test at the latest moment, until the read-write test is completed for all the memory blocks.

After each of the cores completes the read-write test for the corresponding memory block, a test result for the tested memory block may be obtained. To obtain the test result of the entire memory chip, in an embodiment, the test result of each of the memory blocks may include a fact whether a read-write error occurs in a memory cell in the corresponding memory block and number of bits of an address where the read-write error occurs. Therefore, the test result of the memory chip may be obtained by:

determining, according to the test result of each of the memory blocks, a memory cell where the read-write error occurs from the memory chip and the number of bits of the address of the memory cell where the read-write error occurs, to obtain the test result of the memory chip.

After the test result of each of the memory blocks is obtained, it may be counted memory cells where the read-write error occurs from each of the memory blocks and the number of bits of the address of the memory cells where the read-write error occurs. In this way, memory cells where the read-write error occurs from the entire memory chip and the number of bits of the address thereof may be obtained. That is, the test result of the memory chip is obtained.

To sum up, according to the method for testing a memory chip in this exemplary embodiment, memory blocks corresponding to each of the cores in the multi-core processor may be determined, then a read-write test is performed on the corresponding memory block by means of each of the cores in the multi-core processor, and a test result of the memory chip is determined according to a test result of each of memory blocks obtained from the test. In this solution, each of the memory cells in the memory chip is divided into a plurality of memory blocks, and the plurality of memory blocks are allocated to different cores of the multi-core processor, and a read-write test is performed on the corresponding memory blocks by means of each of the cores. In this way, the processing performance of the multi-core processor can be fully utilized, and the test efficiency of the memory chip can be improved.

This exemplary embodiment also provides an apparatus for testing a memory chip. Referring to FIG. 4, the apparatus 400 for testing a memory chip may include: a determination circuit 410, configured to determine a memory block corresponding to each of cores in a multi-core processor, where the memory block is a local memory area comprising a part of memory cells in the memory chip; and a test circuit 420, configured to perform a read-write test on the corresponding memory block by means of each of the cores in the multi-core processor, and determine a test result of the memory chip according to a test result of each of memory blocks obtained from the test.

In an exemplary embodiment of the present disclosure, the determination circuit 410 divides the memory chip into a plurality of memory blocks by: dividing the memory chip into the plurality of memory blocks having memory areas of an equal size or different sizes according to a memory address of each of the memory cells in the memory chip.

In an exemplary embodiment of the present disclosure, the determination circuit 410 may be configured to determine the memory block corresponding to each of the cores according to address information of the memory block corresponding to each of the cores in the multi-core processor, where the address information includes a memory address of each of the memory cells included in each of the memory blocks in the memory chip. The test circuit 420 may be configured to perform the read-write test on the corresponding memory block by means of each of the cores in the multi-core processor until the read-write test is completed for all memory blocks in the memory chip, to obtain the test result of each of the memory blocks.

In an exemplary embodiment of the present disclosure, the test circuit 420 may be further configured to: simultaneously perform the read-write test on any one or more corresponding memory blocks by means of each of the cores in the multi-core processor; or sequentially perform the read-write test on any one or more corresponding memory blocks by means of each of the cores in the multi-core processor.

In an exemplary embodiment of the present disclosure, the test result of each of the memory blocks includes a fact whether a read-write error occurs in a memory cell in the corresponding memory block and number of bits of an address where the read-write error occurs. The test circuit 420 may be further configured to determine, according to the test result of each of the memory blocks, a memory cell where the read-write error occurs from the memory chip and the number of bits of the address of the memory cell where the read-write error occurs, to obtain the test result of the memory chip.

In an exemplary embodiment of the present disclosure, before performing a read-write test on the corresponding memory block by means of each of the cores in the multi-core processor, the test circuit 420 may be further configured to load and run a bootloader by means of the multi-core processor to activate each of the cores in the multi-core processor, such that when each of the cores is in an activated state, the read-write test is performed on the corresponding memory block. The bootloader runs in the SRAM, and each of the cores runs in the bootloader when in the activated state.

In an exemplary embodiment of the present disclosure, when performing a read-write test on the corresponding memory block by means of each of the cores in the multi-core processor, the test circuit 420 may be further configured to determine, when performing the read-write test on each of the memory blocks, a test strategy for each of the memory blocks in the memory chip, where the test strategy includes test procedures for performing a data read operation and/or data write operation on each of the memory blocks. Each of the cores in the multi-core processor performs the data read operation and/or data write operation on each of the corresponding memory blocks according to the test procedures.

In an exemplary embodiment of the present disclosure, the test strategy further includes test data of each of the test procedures, and the test circuit 420 may be further configured to determine target test data for a currently executed test procedure. Each of the cores performs the data read operation and/or data write operation on the target test data in each of the corresponding memory blocks according to the currently executed test procedure.

In an exemplary embodiment of the present disclosure, the test circuit 420 may be further configured to control each of the cores to perform the read-write test on each of the corresponding memory blocks according to a next test procedure when all the cores in the multi-core processor complete the read-write test on each of the corresponding memory blocks according to the currently executed test procedure.

In an exemplary embodiment of the present disclosure, the test circuit 420 may be further configured to, during performing the read-write test on each of the corresponding memory blocks, when any one or more cores in the multi-core processor complete the read-write test on each of the corresponding memory blocks according to the currently executed test procedure, control the any one or more cores to enter a wait state, and trigger a counter to count. Moreover, the test circuit 420 may be further configured to, when determining that all the cores in the multi-core processor enter the wait state according to a counting result of the counter, reactivate each of the cores in the multi-core processor, and control each of the cores to perform the read-write test on each of the corresponding memory blocks according to the next test procedure.

In an exemplary embodiment of the present disclosure, the test strategy further includes an operation procedure for performing a global control operation on the memory cells in the memory chip. The test circuit 420 may be further configured to perform, by any one of the cores in the multi-core processor, the global control operation on all the memory cells in the memory chip according to the operation procedure of the global control operation. The global control operation includes a data retention operation and/or data refresh operation performed on the memory cells in the memory chip.

In an exemplary embodiment of the present disclosure, the test circuit 420 may be further configured to: when there is any one or more memory blocks having not been tested, monitor a test progress for each of the cores, and perform the read-write test on any one of the any one or more memory blocks by means of cores in the multi-core processor having completed the test, until the read-write test is completed for all the memory blocks in the memory chip.

In an exemplary embodiment of the present disclosure, the memory chip includes a dynamic random access memory (DRAM).

Concrete details of each circuit in the above-mentioned apparatus have been described in detail in the method embodiments, and reference may be made to the method embodiments for the details of the undisclosed solution, which is thus not to be repeated.

As will be appreciated by one skilled in the art, aspects of the present disclosure may be embodied as a system, method or program product. Accordingly, aspects of the present disclosure may take the form of an entirely hardware embodiment, an entirely software embodiment (including firmware, micro-code, etc.) or an embodiment combining software and hardware aspects that may all generally be referred to herein as a “circuit,” “circuit” or “system.”

In an exemplary embodiment of the present disclosure, there is further provided a computer-readable storage medium storing a program product capable of implementing the above method in this specification. In some possible embodiments, aspects of the present disclosure may be implemented as a form of a program product, which includes a program code. When the program product runs on a terminal device, the program code is used for enabling the terminal device to perform the steps described in the above “exemplary method” portions of this specification according to the exemplary embodiments of the present disclosure.

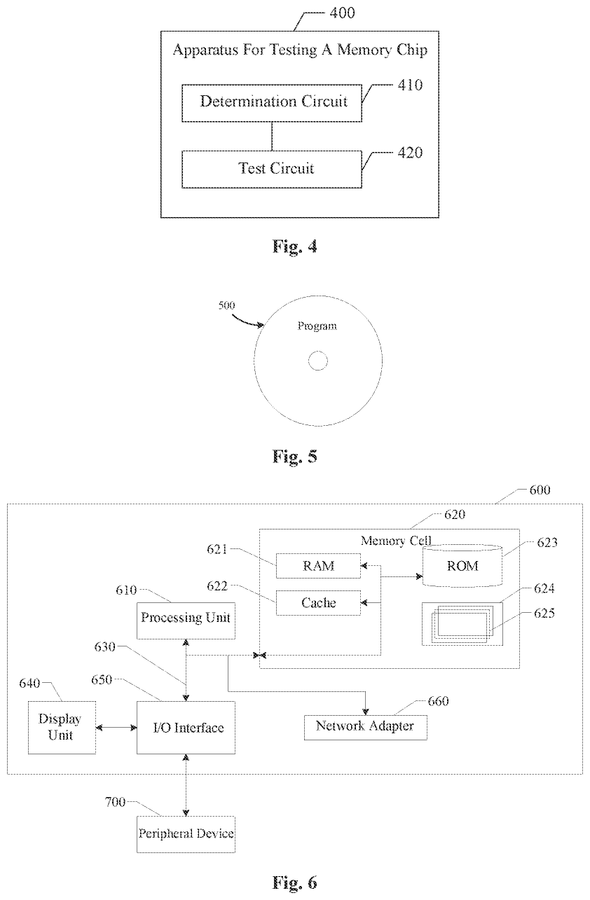

Referring to FIG. 5, a program product 500 configured to implement the above method is described according to the exemplary embodiments of the present disclosure. The program product 500 may adopt a portable compact disc read-only memory (CD-ROM) and include a program code, and may run on a terminal device such as a personal computer. However, the program product of the present disclosure is not limited thereto. In this document, a readable storage medium may be any tangible medium that can contain or store a program for use by or in connection with an instruction execution system, apparatus, or device.

Any combination of one or more readable medium(s) may be utilized by the program product 500. The readable medium may be a readable signal medium or a readable storage medium. The readable storage medium may be, for example, but not limited to, an electronic, magnetic, optical, electromagnetic, infrared, or semiconductor system, apparatus, or device, or any suitable combination of the foregoing. More concrete examples (a non-exhaustive list) of the readable storage medium include the following: an electrical connection having one or more wires, a portable diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

A computer readable signal medium may include a propagated data signal with readable program code embodied therein, for example, in baseband or as part of a carrier wave. Such a propagated data signal may take any of a variety of forms, including, but not limited to, electro-magnetic, optical, or any suitable combination thereof. A readable signal medium may be any readable medium that is not a readable storage medium and that can communicate, propagate, or transport a program for use by or in connection with an instruction execution system, apparatus, or device.

Program code embodied on a readable medium may be transmitted using any appropriate medium, including but not limited to wireless, wireline, optical fiber cable, RF, etc., or any suitable combination of the foregoing.

Program code for carrying out operations of the present disclosure may be written in any combination of one or more programming languages, including an object-oriented programming language such as Java, C++ or the like and conventional procedural programming languages, such as the “C” programming language or similar programming languages. The program code may execute entirely on the user's computing device, partly on the user's computing device, as a stand-alone software package, partly on the user's computing device and partly on a remote computing device or entirely on the remote computing device or server. In a scenario involved with a remote computing device, the remote computing device may be coupled to the user's computing device through any type of network, including a local area network (LAN) or a wide area network (WAN), or may be coupled to an external computing device (for example, through the Internet using an Internet Service Provider).

In an exemplary embodiment of the present disclosure, there is further provided an electronic device capable of implementing the above method. The electronic device 600 according to this exemplary embodiment of the present disclosure is described below with reference to FIG. 6. The electronic device 600 as shown in FIG. 6 is merely an example, and no limitation should be imposed on functions or scope of use of the embodiments of the present disclosure.

As shown in FIG. 6, the electronic device 600 may be shown in the form of a general-purpose computing device. Components of the electronic device 600 may include, but are not limited to: at least one processing unit 610, at least one memory cell 620, a bus 630 connecting different system components (including the memory cell 620 and the processing unit 610), and a display unit 640.

The memory cell 620 stores a program code, which may be executed by the processing unit 610, such that the processing unit 610 performs steps described in the “exemplary method” portions of this specification according to the exemplary embodiments of the present disclosure. For example, the processing unit 610 may perform the method steps as shown in FIG. 1 and FIG. 3 and the like.

The memory cell 620 may include readable media in the form of volatile memory cell, such as a random access memory (RAM) 621 and/or a cache memory 622. Furthermore, the memory cell 620 may further include a read-only memory (ROM) 623.

The memory cell 620 may include a program/utility tool 624 having a group of (at least one) program circuits 625. The program circuits 625 include, but are not limited to: an operating system, one or more applications, other program circuits and program data. Each or a certain combination of these examples may include implementation of network environment.

The bus 630 may represent one or more of a plurality of bus structures, including a memory bus or memory controller, a peripheral bus, an accelerated graphics port, a processing unit or a local bus using any bus structure among the plurality of bus structures.

The electronic device 600 may communicate with one or more peripheral devices 700 (such as keyboards, pointing devices, Bluetooth devices, etc.), and also may communicate with one or more devices allowing a user to interact with the electronic device 600, and/or may communicate with any device (for example, a router, a modem and so on) allowing the electronic device 600 to communicate with one or more other computing devices. This communication may be implemented by means of an input/output (I/O) interface 650. Moreover, the electronic device 600 also may communicate with one or more networks (for example, a local area network (LAN), a wide area network (WAN) and/or a public network such as the Internet) via a network adapter 660. As shown in FIG. 6, the network adapter 660 communicates with other circuits of the electronic device 600 through the bus 630. It should be understood that although not shown in the figures, other hardware and/or software circuits may be used in combination with the electronic device 600, including but not limited to: microcode, device drivers, redundancy processing units, external disk drive arrays, redundant arrays of independent disks (RAID) systems, tape drives and data backup and storage systems, etc.

It is to be noted that although a plurality of circuits or units of a device for action execution have been mentioned in the above detailed description, this partition is not compulsory. Actually, according to the exemplary embodiments of the present disclosure, features and functions of two or more circuits or units as described above may be embodied in one circuit or unit. Reversely, features and functions of one circuit or unit as described above may be further embodied in more circuits or units.

Moreover, the above accompanying drawings are merely illustrative description of processes included in the method according to the exemplary embodiments of the present disclosure and are not intended to limit the present disclosure. It is easy to understand that the processes shown in the above accompanying drawings do not indicate or limit time sequences of these processes. Furthermore, it is also easy to understand that these processes may be executed, for example, synchronously or asynchronously in a plurality of circuits.

With description of the above embodiments, it will be readily understood by those skilled in the art that the exemplary embodiments described herein may be implemented by software or may be implemented by means of software in combination with the necessary hardware. Thus, the technical solution according to the exemplary embodiments of the present disclosure may be embodied in the form of a software product which may be stored in a nonvolatile storage medium (which may be CD-ROM, USB flash disk, mobile hard disk and the like) or on network, including a number of instructions for enabling a computing device (which may be a personal computer, a server, a terminal apparatus, or a network device and the like) to perform the method according to the exemplary embodiments of the present disclosure.

Other embodiments of the present disclosure will be apparent to those skilled in the art from consideration of the specification and practice of the present disclosure disclosed here. The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the following claims.

What is claimed is:

1. A method for testing a memory chip, the method comprising:
determining a memory block corresponding to each of cores in a multi-core processor, the memory block being a local memory area comprising a part of memory cells in the memory chip; and
performing a read-write test on the corresponding memory block by means of each of the cores in the multi-core processor, and determining a test result of the memory chip according to a test result of each of memory blocks obtained from the test.

2. The method according to claim 1, wherein the memory chip is divided into a plurality of memory blocks by:
dividing the memory chip into the plurality of memory blocks having memory areas of an equal size or different sizes according to a memory address of each of the memory cells in the memory chip.

3. The method according to claim 1, wherein the determining a memory block corresponding to each of cores in a multi-core processor comprises:
determining the memory block corresponding to each of the cores according to address information of the memory block corresponding to each of the cores in the multi-core processor, the address information comprising a memory address of each of the memory cells included in each of the memory blocks in the memory chip; and
the performing a read-write test on the corresponding memory block by means of each of the cores in the multi-core processor comprises:
performing the read-write test on the corresponding memory block by means of each of the cores in the multi-core processor until the read-write test is completed for all memory blocks in the memory chip, to obtain the test result of each of the memory blocks.

4. The method according to claim 3, wherein the performing a read-write test on the corresponding memory block by means of each of the cores in the multi-core processor further comprises:
simultaneously performing the read-write test on any one or more corresponding memory blocks by means of each of the cores in the multi-core processor; or
sequentially performing the read-write test on any one or more corresponding memory blocks by means of each of the cores in the multi-core processor.

5. The method according to claim 3, wherein the test result of each of the memory blocks comprises a fact whether a read-write error occurs in a memory cell in the corresponding memory block and number of bits of an address where the read-write error occurs, and the determining a test result of the memory chip according to a test result of each of the memory blocks obtained from the test comprises:
determining a memory cell where the read-write error occurs from the memory chip and the number of bits of the address of the memory cell where the read-write error occurs according to the test result of each of the memory blocks, to obtain the test result of the memory chip.

6. The method according to claim 1, wherein before the performing a read-write test on the corresponding memory block by means of each of the cores in the multi-core processor, the method further comprises:
loading and running a bootloader by means of the multi-core processor to activate each of the cores in the multi-core processor, such that when each of the cores is in an activated state, the read-write test is performed on the corresponding memory block;
wherein the bootloader runs in a static random access memory, and each of the cores runs in the bootloader when in the activated state.

7. The method according to claim 1, wherein when performing a read-write test on the corresponding memory block by means of each of the cores in the multi-core processor, the method further comprises:
when performing the read-write test on each of the memory blocks, determining a test strategy for each of the memory blocks in the memory chip, the test strategy comprising test procedures for performing a data read operation and/or data write operation on each of the memory blocks; and
performing the data read operation and/or data write operation, by each of the cores in the multi-core processor, on each of the corresponding memory blocks according to the test procedures.

8. The method according to claim 7, wherein the test strategy further comprises test data of each of the test procedures, and the performing the data read operation and/or data write operation, by each of the cores in the multi-core processor, on each of the corresponding memory blocks according to the test procedures further comprises:
determining target test data for a currently executed test procedure; and
performing the data read operation and/or data write operation, by each of the cores, on the target test data in each of the corresponding memory blocks according to the currently executed test procedure.

9. The method according to claim 8, further comprising:
when all the cores in the multi-core processor complete the read-write test on each of the corresponding memory blocks according to the currently executed test procedure, controlling each of the cores to perform the read-write test on each of the corresponding memory blocks according to a next test procedure.

10. The method according to claim 9, further comprising:
during performing the read-write test on each of the corresponding memory blocks, when any one or more cores in the multi-core processor complete the read-write test on each of the corresponding memory blocks according to the currently executed test procedure, controlling the any one or more cores to enter a wait state, and triggering a counter to count; and
when determining that all the cores in the multi-core processor enter the wait state according to a counting result of the counter, reactivating each of the cores in the multi-core processor, and controlling each of the cores to perform the read-write test on each of the corresponding memory blocks according to the next test procedure.

11. The method according to claim 7, wherein the test strategy further comprises an operation procedure for performing a global control operation on the memory cells in the memory chip, the method further comprising:
performing, by any one of the cores in the multi-core processor, the global control operation on all the memory cells in the memory chip according to the operation procedure of the global control operation;
wherein the global control operation comprises a data retention operation and/or data refresh operation performed on the memory cells in the memory chip.

12. The method according to claim 3, further comprising:
when there is any one or more memory blocks having not been tested, monitoring a test progress for each of the cores, and performing the read-write test on any one of the any one or more memory blocks by means of cores in the multi-core processor having completed the test, until the read-write test is completed for all the memory blocks in the memory chip.

13. The method according to claim 1, wherein the memory chip comprises a dynamic random access memory.

14. An apparatus for testing a memory chip, the apparatus comprising:
a determination circuit, configured to determine a memory block corresponding to each of cores in a multi-core processor, the memory block being a local memory area comprising a part of memory cells in the memory chip; and
a test circuit, configured to perform a read-write test on the corresponding memory block by means of each of the cores in the multi-core processor, and determine a test result of the memory chip according to a test result of each of memory blocks obtained from the test.

15. A computer-readable storage medium storing a computer program thereon, the computer program is executable by a processor, whereby the method according to claim 1 is implemented.

16. An electronic device, comprising:
a processor; and
a memory, configured to store executable instructions of the processor;
wherein the processor is configured to perform a method for testing a memory chip by executing the executable instructions, the method comprising:
determining a memory block corresponding to each of cores in a multi-core processor, the memory block being a local memory area comprising a part of memory cells in the memory chip; and
performing a read-write test on the corresponding memory block by means of each of the cores in the multi-core processor, and determining a test result of the memory chip according to a test result of each of memory blocks obtained from the test.
